(19) United States
(12) Patent Application Publication
(10) Pub. No.: US 2015/0295134 A1
(43) Pub. Date: Oct. 15, 2015

(54) TRANSPARENT ELECTRONIC SYSTEM AND METHOD

(71) Applicants: Adam Khan, San Francisco, CA (US); Anirudha V. Sumant, Plainfield, IL (US); Kostas Kostopolous, Downers Grove, IL (US)

(72) Inventors: Adam Khan, San Francisco, CA (US); Anirudha V. Sumant, Plainfield, IL (US); Kostas Kostopolous, Downers Grove, IL (US)

(21) Appl. No.: 14/682,947

(22) Filed: Apr. 9, 2015

Related U.S. Application Data
(60) Provisional application No. 61/977,151, filed on Apr. 9, 2014.

(51) Int. Cl. H01L 33/34; H01L 33/00; H01L 27/15

(52) U.S. Cl. CPC H01L 33/34; H01L 27/15; H01L 33/0054

(57) ABSTRACT

A system and method for transparent diamond semiconductor electronics are provided. The system may include a transparent substrate, a diamond active layer, a conductive layer, and an application that incorporates the transparent layer, the diamond layer, and the conductive layer. The method may include selecting a transparent substrate, creating a diamond material having a diamond lattice on the substrate, introducing acceptor dopant atoms to the diamond lattice to create ion tracks, introducing substitutional dopant atoms, annealing the diamond lattice, adding a conductive layer to the diamond lattice, and incorporating the substrate, and the diamond lattice, and the conductive layer into an application.

### CROSS-REFERENCE TO RELATED APPLICATION

This application claims the benefit of U.S. Provisional Application No. 61/977,151, filed Apr. 9, 2014, which is fully incorporated herein by reference.

### STATEMENT REGARDING FEDERALLY SPONSORED RESEARCH OR DEVELOPMENT

The United States Government has rights in this invention pursuant to Contract No. DE-AC02-06CH11357 between the United States Government and UChicago Argonne, LLC, representing Argonne National Laboratory.

### BACKGROUND

1. Field

This invention is generally related to electronic semiconductor systems and methods, and more particularly to a system and method for transparent diamond semiconductor electronics.

2. Background

Diamond possesses favorable theoretical semiconductor performance characteristics, including the possibility of creating transparent electronics. However, practical diamond based semiconductor device applications remain limited.

### SUMMARY

Disclosed herein is a new and improved system and method for transparent diamond semiconductor electronics. In accordance with one aspect of the approach, a system for transparent diamond semiconductor electronics may include a transparent substrate, a diamond active layer, a conductive layer, and an application that incorporates the transparent layer, the diamond layer, and the conductive layer.

In another approach, a method of fabricating a transparent electronic device, may include the steps of selecting a transparent substrate, creating a diamond material having a diamond lattice on the transparent substrate, introducing a minimal amount of acceptor dopant atoms to the diamond lattice to create ion tracks, introducing substitutional dopant atoms to the diamond lattice through the ion tracks, annealing the diamond lattice, where the introduction of the minimal amount of acceptor dopant atoms does not create a critical density of vacancies, and the introduction of the minimal amount of acceptor dopant atoms diminishes the resistive pressure capability of the diamond lattice, adding a conductive layer to the diamond lattice, and incorporating the substrate, and the diamond lattice, and the conductive layer into an application.

Other systems, methods, aspects, features, embodiments and advantages of the system for transparent diamond semiconductor electronics disclosed herein will be, or will become, apparent to one having ordinary skill in the art upon examination of the following drawings and detailed description. It is intended that all such additional systems, methods, aspects, features, embodiments and advantages be included within this description, and be within the scope of the accompanying claims.

### BRIEF DESCRIPTION OF THE DRAWINGS

It is to be understood that the drawings are solely for purpose of illustration. Furthermore, the components in the figures are not necessarily to scale, emphasis instead being placed upon illustrating the principles of the system disclosed herein. In the figures, like reference numerals designate corresponding parts throughout the different views.

FIG. 1 is top view of a demonstrative transparent electronic device.

FIG. 2 is a side view of the demonstrative transparent electronic device of FIG. 1.

FIG. 3 is a block diagram of an embodiment of a method for fabricating a transparent electronic device, such as the transparent electronic device of FIG. 1.

### DETAILED DESCRIPTION

The following detailed description, which references to and incorporates the drawings, describes and illustrates one or more specific embodiments. These embodiments, offered not to limit but only to exemplify and teach, are shown and described in sufficient detail to enable those skilled in the art to practice what is claimed. Thus, for the sake of brevity, the description may omit certain information known to those of skill in the art.

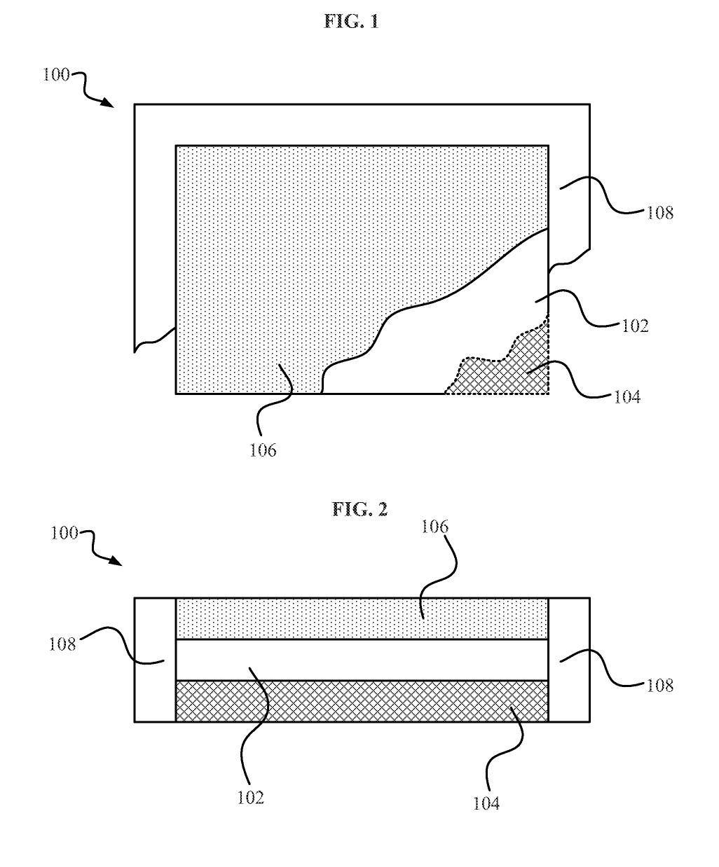

FIG. 1 shows a top view of a demonstrative exemplary transparent electronic device 100. The device 100 includes an active layer 102, a substrate layer 104, a conductive layer 106, and an application 108. Active layer 102 may be a diamond layer. The active layer 102 may be doped to have semiconducting properties. The active layer 102 may include n-type doped diamond, p-type doped diamond, and a combination of n-type and p-type doped diamond. The active layer 102 may include nano crystalline diamond and ultrananocrystalline diamond.

In FIG. 1, active layer 102 is shown with cutaways for only for illustration and differentiation of layer 102, from layers 104 and 106. It is contemplated that the layers 102, 104, and 106 will generally be co-extensive, as shown in FIG. 2.

The active layer 102 may include one or more light emitting diodes (LEDs). LEDS may be formed from materials that include, but are not limited to, gallium nitride and diamond. Active layer 102 may include a camera (not shown). The camera may include a charge coupled device (CCD) and may be formed from diamond material.

In some embodiments, the active layer 102 may be formed from diamond material that is formed using the systems and methods disclosed and described in U.S. Patent Publication No. 2013/0026492, by Adam Khan, and published on Jan. 31, 2013, which is fully incorporated herein by reference. In some embodiments, the active layer 102 may be formed from diamond material that is formed using the systems and methods disclosed and described in U.S. Pat. No. 8,354,290, issued to Anirudha Sumant, et al, on Jan. 15, 2013 which is fully incorporated herein by reference. In other embodiments, the active layer 102 may be formed from combinations of the systems and methods disclosed and described in the above mentioned '492 Publication and the '290 Patent.

An active layer 102 formed from diamond may allow for improved heat conductivity that would allow heat to be efficiently transported from the operating portions of the active layer 102 to portions of the application 108 that are more heat tolerant. Thus, a diamond active layer 102 may operate as a semiconducting device and a heat dissipation system.

In some embodiments, the CCD and/or the LED may be formed from with the systems and methods disclosed in one, or both, of the '492 Publication and the '290 Patent. The CCD and/or the LED may be formed from such systems and methods from n-type diamond material.

Substrate layer 104 may be formed from materials that include, but are not limited to, glass, fused silica, and sapphire. Though shown in FIG. 1 as cross-hatched to illustrate the separation of layer 102 and layer 104, substrate layer 104 may be transparent and/or substantially transparent.

Conductive layer 106 may be formed from materials that include, but are not limited to, indium phosphide, indium tin oxide (ito), florine tin oxide (fto), graphene, and graphene oxide. In some applications, the conductive layer 106 may be covered by an additional layer (not shown) of semiconducting material, such as, but not limited to diamond and fused silica.

The active layer 102, the substrate layer 104, and the conductive layer 106 may all be formed from materials that are transparent, or substantially transparent in the visible light wavelengths. As used herein, the term “transparent” includes materials that are substantially transparent. For substantially transparent materials the layers may be transparent to the extent that a user of normal vision would be able to clearly view objects while looking through the layers without substantial impairment of vision in regard to the objects seen through the layers, at least when the layers are not activated in order to provide visual information to the user.

Application 108 may represent either a physical device, such as a frame for glasses or a window frame, or may represent the incorporation of the active layer 102, the substrate layer 104, and the conductive layer 106 into another application, such as glasses or a window frame. For example, application 108 may include, but is not limited to, an electronic display device, a flat screen television, a tintable window, a portable hand-held electronic device, a tablet, a phone, a computer, a wristwatch, glasses, goggles, and other wearable electronics. The application 108 may represent a physical frame for the layers 102, 104, and 106, and may represent an operating device that incorporates the layers 102, 104, and 106. Application 108 is illustrated in FIG. 1 to show that application 108 may partially surround the edges of layers 102, 104, and 106. In some embodiments, application 108 may completely surround the edges of layers 102, 104 and 106.

The application 108 may also include virtual reality devices, including glasses, goggles, and helmets. Such virtual reality devices may include additional sensors and outputs (not shown) associated with a users senses and limbs, as is known to those having ordinary skill in the art. The application 108 may also be associated with various wired and wireless information networks, such as the Internet. The application 108 may allow for holographic vision, particularly when in the form of such virtual reality devices. The application 108 may include glasses having a first and a second lens. For an application 108 in which the layers may be close to a user, for example where the application involves glasses, goggles, or helmets, where the substrate layer 106 is placed between the active layer 102 and the skin of the user, the substrate layer 106 may deflect heat from the user.

Such electronic display devices may include LEDs that are transparent when in an inactive state, and that may illuminate in an active state, to provide information on the electronic display device. The LEDs may be arranged to provide information and may be programmably activated. The LEDs may be arranged in a grid and may function as pixels in the electronic display device. The LEDs may be arranged and activated to form images. The LEDs may be formed to illuminate in various colors. The LEDs may be arranged and activated to form moving images. In such applications as described herein, the application 108 may be, but is not limited to, a movie player, a computer graphics displayer, and a video game.

Touch sensors (not shown) may also be incorporated into the application 108, or into the layers 102, 104, and 106. The touch sensors may be used to control the operation of the application 108 through a menu, or other control system.

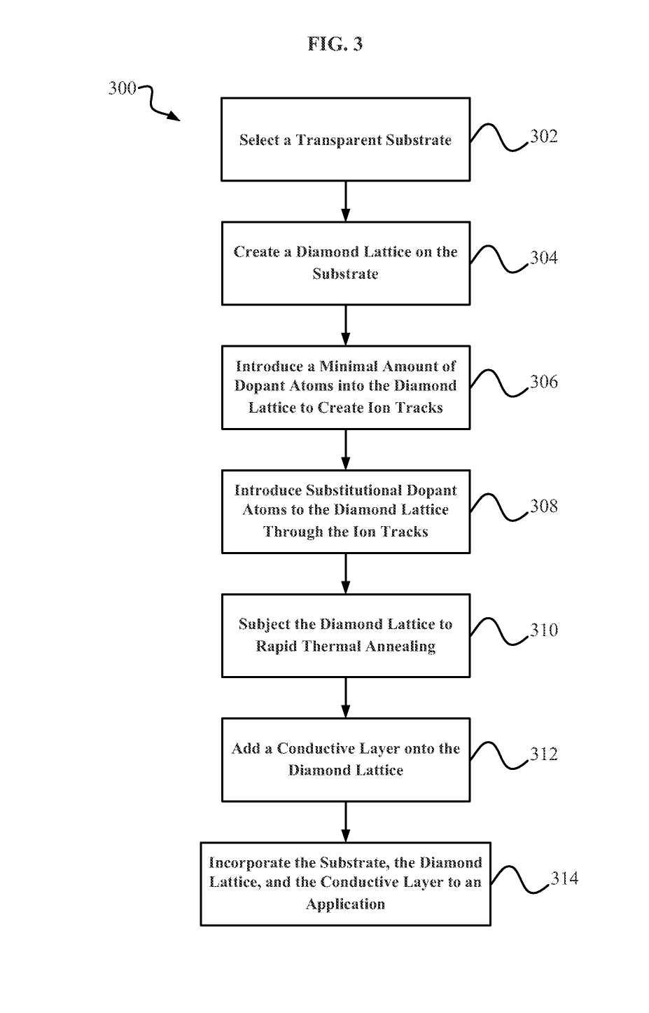

FIG. 3 shows a block diagram of an embodiment of a method 300 for fabricating a transparent electronic device, such as transparent electronic device 100. Method 300 may include a first step 302 of selecting a transparent substrate, such as substrate layer 104.

Method 300 may include a second step 304 of creating a diamond lattice on the substrate layer of step 302, for example, but not limited to, using the systems and methods disclosed in the '290 Patent. Step 304 may include placing a bottom electrode on the substrate, and depositing layers of ultrananocrystalline diamond (UNCD) thin films on the bottom electrode by microwave chemical vapor deposition (CVD) with a microwave CVD plasma gas comprising argon (Ar), methane (CH₄) and hydrogen (H₂) to form multilayered UNCD dielectric films.

The method 300 may include a third step 306 of introducing a minimal amount of acceptor dopant atoms to the diamond lattice to create ion tracks. For example, by introducing a minimal amount of acceptor dopant atoms to an active layer, such as active layer 102. The creation of the ion tracks may include creation of a non-critical concentration of vacancies, for example, less than 10²²/cm³ for single crystal bulk volume, and a diminution of the resistive pressure capability of the active layer, for example active layer 102. For example, third step 306 may include introducing the acceptor dopant atoms using ion implantation at approximately 293 to 298 degrees Kelvin (K) in a low concentration. The acceptor dopant atoms may be p-type acceptor dopant atoms. The p-type dopant may be, but is not limited to, boron, hydrogen and lithium. The minimal amount of acceptor dopant atoms may be such that carbon dangling bonds will interact with the acceptor dopant atoms, but an acceptor level is not formed in the diamond lattice.

The minimal amount of acceptor dopant atoms of third step 306 may be for example, but is not limited to, approximately 1×10¹⁰/cm³ of boron. In other embodiments, the minimal amount of acceptor dopant atoms of third step 306 may be for example, but is not limited to, approximately 5×10¹⁰/cm³ of boron and a range of 1×10⁸/cm³ to 5×10¹⁰/cm³. Third step 306 may be accomplished by boron co-doping at room temperature in that created vacancies may be mobile, but boron may take interstitial positioning. The third step 306 may create mobile vacancies for subsequent dopants, in addition to some substitutional positioning.

The ion tracks of third step 306 may be viewed as a ballistic pathway for introduction of larger substitutional dopant atoms (see fourth step 308 below). Third step 306 may also eliminate the repulsive force (with respect to the substitutional dopant atoms (see step 308 below)) of the carbon dangling bonds in the diamond lattice by energetically favoring interstitial positioning of the acceptor dopant atoms, and altering the local formation energy dynamics of the diamond lattice.

The fourth step 308 of method 300 may include introducing the substitutional dopant atoms to the diamond lattice through the ion tracks. For example, fourth step 308 may include introducing the larger substitutional dopant atoms using ion implantation preferably at or below approximately 78 degrees K for energy implantation at less than 500 keV. Implanting below 78 degrees K may allow for the freezing of vacancies and interstitials in the diamond lattice, while maximizing substitutional implantation for the substitutional dopant atoms. The larger substitutional dopant atoms may be for example, but is not limited to, phosphorous, nitrogen, sulfur and oxygen.

For implantation where the desired ion energy is higher, as local self-annealing may occur, it may be beneficial to use ambient temperature in conjunction with MeV energy implantation. Where the desired ion energy is higher, there may be a higher probability of an incoming ion taking substitutional positioning.

The larger substitutional dopant atoms may be introduced at a much higher concentration than the acceptor dopant atoms. The higher concentration of the larger substitutional dopant atoms may be, but is not limited to, approximately 9.9×10¹⁷/cm³ of phosphorous and a range of 8×10¹⁷ to 2×10²¹/cm³.

In fourth step 308, the existence of the ballistic pathway and minimization of negative repulsive forces acting on the substitutional dopant atoms facilitates the entry of the substitutional dopant atoms into the diamond lattice with minimal additional lattice distortion. Ion implantation of the substitutional dopant atoms at or below approximately 78 degrees K provides better impurity positioning, favoring substitutional positioning over interstitial positioning, and also serves to minimize the diamond lattice distortions because fewer vacancies are created per impinging ion.

In one embodiment, ion implantation of step 308 may be performed at 140 keV, at a 6 degree offset to minimize channeling. Implant beam energy may be such that dosages overlap in an active implant area approximately 25 nm below the surface so that graphitic lattice relaxation is energetically unfavorable. Doping may be performed on a Varian Ion Implantation System with a phosphorus mass 31 singly ionized dopant (i.e., 31P+); a beam current of 0.8 μA; a beam energy of 140 keV; a beam dose 9.4×10¹¹/cm²; an incident angle of 6 degrees; and at a temperature of at or below approximately 78 degrees K.

The fifth step 310 of method 300 may include subjecting the diamond lattice to rapid thermal annealing. The rapid thermal annealing may be done at 1000 degree celsius C. Rapid thermal annealing may restore portions of the diamond lattice that may have been damaged during the third step 306 and the fourth step 308 and may electrically activate the remaining dopant atoms that may not already be substitutionaly positioned. Higher temperatures at shorter time durations may be more beneficial than low temperature, longer duration anneals, as the damage recovery mechanism may shift during long anneal times at temperatures in excess of 600C.

The sixth step 312 of method 300 may include adding a conductive layer onto the diamond lattice. For example, the sixth step 312 may include adding a conductive layer 106 onto the active layer 102. In additional embodiments, the sixth step may include the systems and methods disclosed in U.S. Pat. No. 8,933,462 issued to Adam Khan on Jan. 13, 2015, which is fully incorporated herein by reference.

The seventh step 314 of method 300 may include incorporating the substrate layer, the diamond layer, and the conductive layer into an application. For example, the seventh step 314 may include incorporating the substrate layer 104, the active layer 102, and the conductive layer 106, into the application 108.

The word “exemplary” is used herein to mean “serving as an example, instance, or illustration.” Any embodiment or variant described herein as “exemplary” is not necessarily to be construed as preferred or advantageous over other embodiments or variants. All of the embodiments and variants described in this description are exemplary embodiments and variants provided to enable persons skilled in the art to make and use the invention, and not necessarily to limit the scope of legal protection afforded the appended claims.

The above description of the disclosed embodiments is provided to enable any person skilled in the art to make or use that which is defined by the appended claims. The following claims are not intended to be limited to the disclosed embodiments. Other embodiments and modifications will readily occur to those of ordinary skill in the art in view of these teachings. Therefore, the following claims are intended to cover all such embodiments and modifications when viewed in conjunction with the above specification and accompanying drawings.

We claim:

1. A transparent electronic device, comprising:
a transparent substrate;
a diamond active layer;
a conductive layer; and
an application that incorporates the transparent layer, the diamond layer, and the conductive layer.

2. The transparent electronic device of claim 1, where the transparent substrate material is selected from the group that consists of glass, fused silica, and sapphire.

3. The transparent electronic device of claim 1, where the conductive layer material is selected from the group that consists of indium phosphide, indium tin oxide, florine tine oxide, graphene, and graphene oxide.

4. The transparent electronic device of claim 1, where the active layer includes one or more light emitting diodes.

5. The transparent electronic device of claim 1, where the active layer includes a charge coupled device.

6. The transparent electronic device of claim 1, where the application is a frame for glasses.

7. The transparent electronic device of claim 1, where the application is a phone.

8. The transparent electronic device of claim 1, where the application is a virtual reality device.

9. The transparent electronic device of claim 1, where the application is a video game.

10. A method of fabricating a transparent electronic device, the method including the steps of:
selecting a transparent substrate;
creating a diamond material having a diamond lattice on the transparent substrate;
introducing a minimal amount of acceptor dopant atoms to the diamond lattice to create ion tracks;
introducing substitutional dopant atoms to the diamond lattice through the ion tracks;
annealing the diamond lattice, where the introduction of the minimal amount of acceptor dopant atoms does not create a critical density of vacancies, and the introduction of the minimal amount of acceptor dopant atoms diminishes the resistive pressure capability of the diamond lattice;
adding a conductive layer to the diamond lattice; and
incorporating the substrate, and the diamond lattice, and the conductive layer into an application.
